(19) United States
(12) Patent Application Publication
(10) Pub. No.: US 2013/0065706 A1
(43) Pub. Date: Mar. 14, 2013

(54) GOLF CLUB HEAD

(71) Applicants: Sharon J. PARK, Irvine, CA (US); Joseph C. CHEN, Costa Mesa, CA (US)

(72) Inventors: Sharon J. PARK, Irvine, CA (US); Joseph C. CHEN, Costa Mesa, CA (US)

(73) Assignee: SRI SPORTS LIMITED, KOBE-SHI (JP)

(21) Appl. No.: 13/232,592

(22) Filed: Sep. 14, 2011

(51) Int. Cl. A63B 53/04; C23C 16/06; C23C 16/44; B23P 17/04; B23P 15/00

(52) U.S. Cl. 473/348; 29/527.1; 473/324; 473/349; 427/248.1; 427/255.7; 427/249.17; 427/249.18; 427/249.19; 427/255.394; 427/250

(57) ABSTRACT

An approach is provided for coating a golf club head with a material. The approach involves securing a first golf club head component to a second golf club head component using an adhesive, resulting in a golf club head main body having an exterior surface. The approach further includes physical vapor depositing at least one layer on at least a portion of the exterior surface of the golf club head main body at a temperature less than a melting point of the adhesive.

### COPYRIGHT AUTHORIZATION

The disclosure below may be subject to copyright protection. The copyright owner has no objection to the facsimile reproduction by any one of the documents containing this disclosure, as they appear in the Patent and Trademark Office records, but otherwise reserves all applicable copyrights.

### BACKGROUND

Conventional golf club heads, particularly iron-type club heads, may be formed of a unitary structure, e.g. by investment casting. However, in some cases, it is advantageous to form the club head of plural components, particularly to optimize material properties for specific locations about the club head and/or to reduce material costs. For example, in use, a striking face of a club head impacts a golf ball and is thus subjected to considerable forces during a golf shot. Thus, the striking face is often formed as a separate club head component, secured to a main club head body, of a material specifically suited for such impact.

Ordinarily, a striking face insert of a multicomponent golf club head is secured to the main body by any number of means, for example press-fitting, interference fitting, welding, brazing, or other mechanical attachment means or material bonding means. In some cases, chemical adhesives are applied exclusively for such attachment, or in addition to another attachment means as a further precaution against separation.

It is also desirable to further enhance the strength, durability, hardness, aesthetics, wear resistance, or other properties of any surface portion of the golf club head, e.g. the striking face, by applying any of a variety of surface coatings or treatments. However, conventional coating methods, such as physical vapor depositing, may degrade the structural integrity of the golf club head, as well as preclude or frustrate certain striking face insert attachment processes, due to the environment in which such coating processes are performed.

### SUMMARY

There is a need to manufacture a golf club head having a dark, durable, performance-enhancing finish while maintaining the structural integrity of the golf club head.

According to one embodiment, a method comprises securing a first golf club head component to a second golf club head component using an adhesive, resulting in a golf club head main body having an exterior surface. The method further comprises physical vapor depositing at least one layer on at least a portion of the exterior surface of the golf club head main body at a temperature less than a melting point of the adhesive.

According to another embodiment, a golf club head comprises a first club head component and a second club head component secured to the first club head component with an adhesive so as to form an exterior surface. The golf club head further comprises at least one layer that is physical vapor deposited on at least a portion of the exterior surface of the golf club head at a temperature less than a melting point of the adhesive.

According to another embodiment, a method comprises providing a golf club component of a first material, the golf club component having an exterior surface. The method further comprises physical vapor depositing at least one layer on at least a portion of the exterior surface of the club head component at a temperature no greater than 200° C.

These and other features and advantages of the golf club head according to the invention in its various aspects, as provided by one or more of the various examples described in detail below, will become apparent after consideration of the ensuing description, the accompanying drawings, and the appended claims. The accompanying drawings are for illustrative purposes only and are not intended to limit the scope of the present invention.

### BRIEF DESCRIPTION OF THE DRAWINGS

FIG. 1 is a front elevational view of a golf club head according to one or more embodiments;

FIG. 2 is a cross-sectional view of the golf club head of FIG. 1, in the plane A-A′ illustrated in FIG. 1, according to one or more embodiments;

FIG. 2(a) is a detail of the cross-sectional view of FIG. 2; and

FIG. 3 is a flow chart of a process for coating a golf club head according to one embodiment of the invention.

### DETAILED DESCRIPTION

Conventional golf club heads comprise a body having a striking face. The striking face is typically unitarily formed with the body, but may be a separate club head component, such as a striking face insert, secured to the body forming a multicomponent golf club head. A multicomponent golf club head may also have alternative, or additional, features such as a backing plate, sole plate, weight member, vibration damping insert and the like. Ordinarily, the striking face insert, or any other component of a multicomponent golf club head, comprises an insert that is secured to the body by any number of attachment means.

The striking face comes into contact with a golf ball when struck and, as such, the striking face is subjected to considerable forces during a golf shot. Other features of a multicomponent golf club head are subjected to various vibrations that are a result of the impact a golf club experiences during a golf shot, such vibrations affecting the acoustic response and/or feel of the club head.

To enhance the golf club head's performance, as well as the golf club head's durability and appearance, any portion of the golf club head may be coated with any of a variety of surface coatings. Any such coatings may be a dark, durable, performance-enhancing finish, but the coating may also be a non-dark coating, or any coating that affects the look of the golf club and/or the performance of the golf club head.

Conventional coating methods such as physical vapor deposition (PVD), however, may degrade the structural integrity of the golf club head, in part, because of the environment in which the coating process take place, e.g. the temperature(s) at which the coating processes are performed. Further, preparing such a coated golf club head presents numerous additional challenges. For example, before securing the striking face insert or any other component to the club head body, an adhesive may optionally be applied to the striking face insert or other component as an additional assurance against separation of the striking face insert or other component from the club head body due to the force applied to the golf club head when striking a golf ball. The additional adhesive layer is also a preventative against separation of the striking face insert or any other component from the club head body due to improper ball striking by mishit golf shots. The same holds true for any other component of a multi-component golf club head.

PVD processes are conducted at elevated temperatures, that is, above 200° C. and normally between 200° C. and 400° C. and even higher. These conventional PVD process temperatures are above the melting point of a cured adhesive that may be used to affix a striking face insert or any other component to the club body. Melted glue causes numerous problems such as: small boundary cracks after excessive impacts on the striking face, melting glue running to surfaces where it is not intended, cosmetic discoloration of the coating applied during the PVD process, etc.

Accordingly, there is a need to manufacture a golf club head having a dark, durable, performance-enhancing finish while maintaining the structural integrity of the golf club head using a “low” temperature PVD process that is below conventional PVD process temperatures.

Physical vapor deposition is a generic term used to describe a family of coating processes. All the processes are fundamentally vaporization coating processes in which the basic mechanism is a transfer of material from the solid phase to the vapor phase and then back to the solid phase. In the vaporization phase, a solid material such as a metal is sublimated to form a gas under high temperatures and reduced pressures and subsequently deposited as a solid on the object to be coated. The vapors are transported through a vacuum or partial vacuum by the energy of the vapor particles.

Chemical compounds rather than elemental metal coatings may be deposited by introducing a reactive gas in the PVD chamber that reacts with the metal vapor from the PVD source to form the desired coating compound. Examples of such reactive gases include nitrogen, oxygen or simple hydrocarbons such as acetylene. Using nitrogen as the reactive gas yields coating compounds that are nitrides. Oxygen yields compounds that are oxides. Hydrocarbons yield compounds that are carbides. Mixtures of nitrogen and hydrocarbons yield carbonitrides.

Depending on the metal vapor, the gaseous component, and the respective ratios of each, the colors of the coating material may be varied over a wide range including pink, gold and dark gray to black, for example. Some reactions between the target materials and the reactive gases may take place at the substrate being coated simultaneously with the deposition process. Generally, there are three basic categories of processes known as PVD processes: ion plating, evaporation and sputtering.

PVD coatings are desirable because they are often harder and more corrosion resistant than coatings prepared by electroplating. PVD coatings conventionally outperform painted coatings with respect to durability. Most PVD coatings have high temperature resistance, good impact strength, possess excellent abrasion resistance and are extremely durable.

When coating a steel object, for example, PVD processes are preferred because the deposition temperature exceeds the austenitzing temperature of steel. While an example is provided for a steel object, PVD processes have a number of advantages for coating any metal or other material that a PVD coating may be applicable to such as titanium, copper, brass, nickel, brass, other metal, polymer, etc.

PVD coatings are deposited as highly adhered, pure metal or alloy coatings on the surface of the substrate. The thickness of the coating layer typically ranges from between 0.5 to 10 microns (μ), more preferably between 0.5 and 5 microns. The layers can be deposited singly or as multi-layer coatings. All these properties make PVD processes and PVD coatings preferable for use in preparing golf club heads having improved performance and appearance.

Before beginning any PVD process, the part to be coated should have all burrs removed to prevent exposure of uncoated metal when the burrs are later broken off. The surface of the object to be coated (substrate) should also be thoroughly cleaned because conditions that reduce film adhesion such as the presence of surface oxides, grinding burrs, imbedded polishing compounds and rust-preventive films inhibit the deposition process and formation of uniform layers of the coating material.

It should be noted that although a process is generally described in which the striking face insert, or other component, is both secured and optionally adhesively attached to the club head body, alternative embodiments are envisioned in which the adhesive layer is omitted and/or the striking face is unitarily formed with the club head body. Even in these alternative cases, issues arise, such as discoloration of the coating applied, or degradation in the structural integrity of the golf club head. Accordingly, an attractive golf club head with improved appearance and performance may be prepared with or without the precautionary adhesive layer if the PVD coating process is conducted at relatively low temperatures.

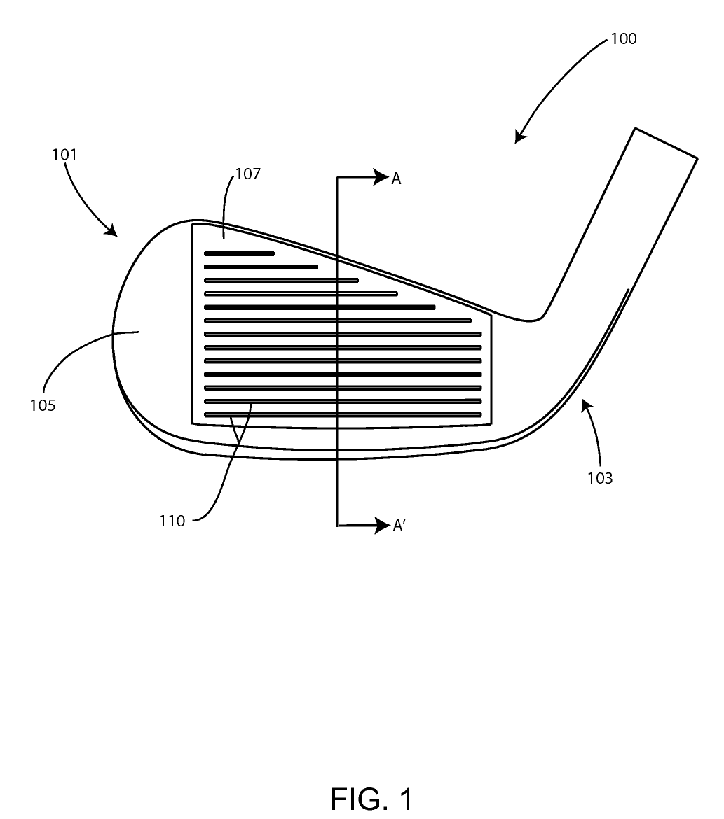

In one or more embodiments, and as depicted by way of example in FIGS. 1 through 3, a golf club head 100 comprises an iron-type golf club head. It is noted, however, that while the golf club head 100 is illustrated as an iron-type golf club head, the golf club head 100 may be any of, e.g., an iron-type, putter-type, wood-type, hybrid-type, etc. It is further noted that while the golf club head 100 is illustrated as being a right-handed golf club head, any reference to any position on the golf club head 100 may be mirrored and applied to a left-handed golf club head.

FIG. 1 depicts a front elevational view of a golf club head 100 prepared using a low-temperature PVD process as discussed above according to one embodiment of the invention. The golf club head 100 comprises a body 101, a hosel 103 and a striking face 105. In some embodiments, the body 101 may be formed from any of stainless steel, titanium, aluminum, copper, polymer and a fiber reinforced polymer (FRP). According to one embodiment, the body 101 is made from a metal, such as 17-4 stainless steel (a chromium-nickel-copper stainless steel).

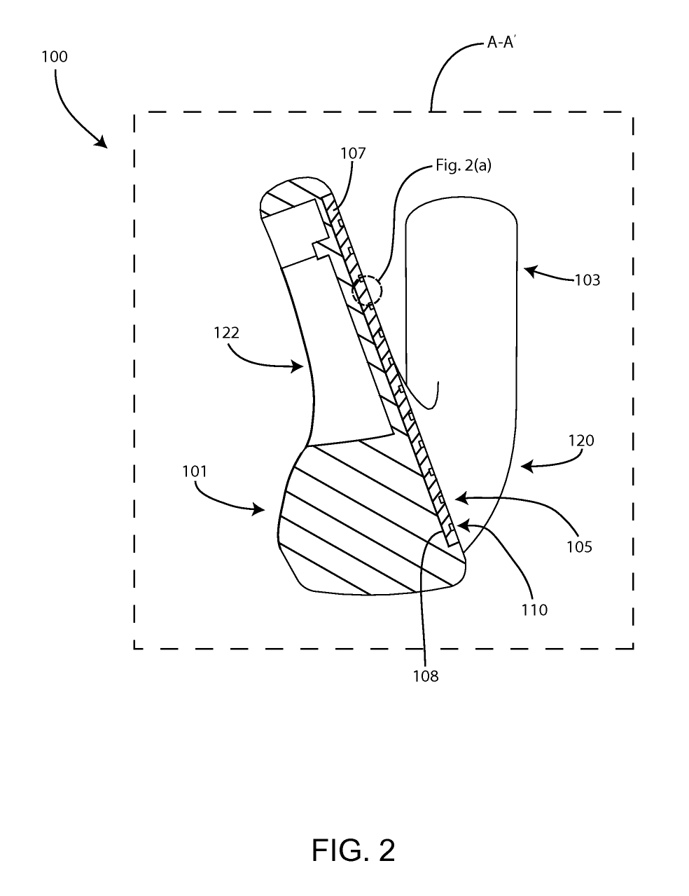

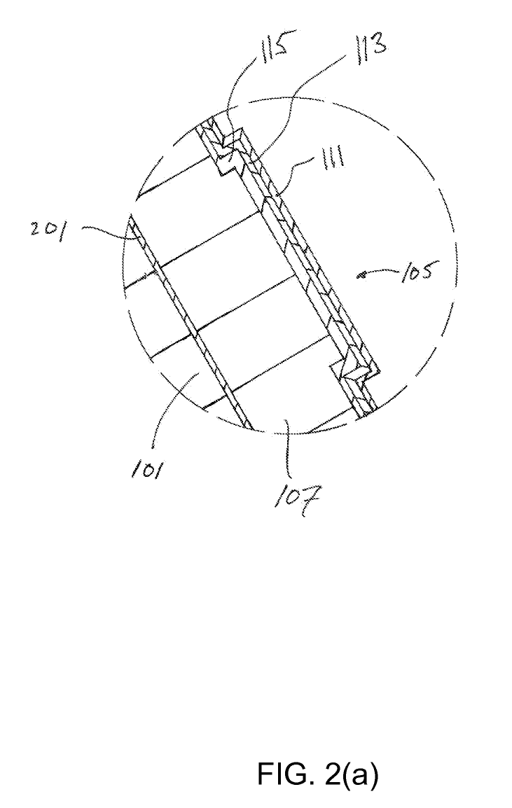

As shown in FIG. 1, the striking face 105 comprises a striking face insert 107. The striking face insert 107, which is secured to the body 101, may be secured to a receiving portion 108 (see FIG. 2) of the body 101, by any suitable means including mechanical press fitting, interference fitting, welding, pinning or by adhesion, etc. for example. The receiving portion 108, according to one embodiment, is a recess, but may take any form that may readily accept an additional component for securing to the golf club head 100. The striking face insert 107 may be made from any suitable material selected from stainless steel, titanium, aluminum, copper, polymer and a fiber reinforced polymer (FRP). Preferably, the striking face insert 107 is formed of titanium or a titanium alloy because of its high tensile strength to weight properties. A useful titanium insert is prepared from titanium 6-4 (an alloy of titanium containing 6% aluminum and 4% vanadium).

The striking face insert 107, as illustrated, includes scorelines or grooves 110 optionally machined into the ball-striking surface of the striking face 105. But, the striking face insert 107, in alternative embodiments, may be a smooth surface without scorelines (for example, in the case of a putter-type golf club head, or wood-type golf club head). Any scorelines 110 that are present on the striking face insert 107 may be masked during the PVD process or left unmasked.

According to various embodiments, with reference to FIGS. 1 and 2, a backing plate or damping member (not shown) may be inserted between the golf club body 101 and the striking face insert 107, or secured to any other portion of the golf club head 100. The backing plate or damping member gives the finished golf club head a more solid feel when striking the ball and assists in damping any vibration or unacceptably high noise level when the golf club head strikes a golf ball in a golf shot. The backing plate or damping member may be secured to any portion of the body 101 by any suitable means including mechanical press fitting, welding, pinning or by adhesion, etc. for example.

FIG. 2 illustrates a cross sectional view of the golf club head 100 in plane A-A′ illustrated in FIG. 1. FIG. 2(a) illustrates a detail of FIG. 2 showing the surface structure of a portion of the striking face 105 of the club head 100. The golf club head 100 is coated using the PVD processes discussed above. It should be noted that while FIG. 2(a) illustrates the golf club head 100 having multiple layers of materials, and components, any arrangement of layers is possible, i.e. some layers may be omitted.

The golf club head body 101 has an adhesive layer 201 applied between the striking face insert 107 and the club head body 101. In some embodiments, the adhesive is applied at discrete, spaced apart locations or over an area covering only a portion of the junction between the striking face insert 107 and the main body 101. The club head body 101 includes a front portion 120 and a rear portion 122 opposite the front portion. The club head body 101 has a recess 108, located proximate the front portion 120, in which the striking face insert 107 is secured.

In some embodiments, an adhesive is applied between the striking face insert 107 and/or the backing plate or damping member 109, optionally a one-part epoxy having a melting point for the cured adhesive of less than 200° C. For example, in some embodiments, the adhesive is one that is manufactured by the 3M Company under the trade name EW-2010. The surface of the club head body should be thoroughly cleaned and the surface allowed to dry completely before the adhesive is applied. The adhesive may be cured for 60 minutes at 120° C. or for 20 minutes at 140° C. Cleanup of applying the adhesive may be accomplished with methyl ethyl ketone (MEK), for example.

According to various embodiments, a coating 111 may be applied selectively to the striking face insert 107, or, in some embodiments, applied selectively to another portion of the golf club head 100. The coating 111 is preferably a metal chosen from the group consisting of vanadium, chromium, zirconium, titanium, niobium, molybdenum, hafnium, tantalum, and tungsten, and, in some embodiments, the coating 111 also includes a nonmetal selected from a group consisting of a nitride and a carbide. The coating 111 is applied to the striking face insert 107 by a low temperature PVD process as described above. A low-temperature PVD process is a PVD process conducted at temperatures below conventional PVD processing temperatures of from about 200° C. to about 400° and above. If the striking face insert 107 is secured using an adhesive, the “low temperature” PVD process is particularly advantageous because temperatures below 200° C. are typically below the melting point of the adhesive when it is cured.

Therefore, to avoid any of the problems discussed above associated with conventional PVD processes, according to one embodiment, the coating process may be conducted at a temperature of below 200° C. In another embodiment, the coating process may be conducted at a temperature no greater than 150° C. In a further embodiment, the coating process may be conducted at a temperature no greater than 110° C.

According to various embodiments, another coating 113 may be applied selectively to the striking face insert 107 or it may be applied selectively to any portion of the golf club head 100. The coating 113, which may be a same material as the coating 111 discussed above, or different, is overlayed by the coating process discussed above. In some embodiments, the coating 113 may be a metal chosen from the group consisting of vanadium, chromium, zirconium, titanium, niobium, molybdenum, hafnium, tantalum, and tungsten, and, in some embodiments, the coating may include a nonmetal selected from the group consisting of a nitride and a carbide. Preferably, the coating 113 is formed of zirconium. The coating 113 is applied to the striking face insert 107 by a low temperature PVD process as described above. A “low temperature” PVD process is a PVD process conducted at temperatures below the ordinary PVD processing temperatures of from 200° C. to 400° and above. In embodiments where the striking face insert 107 is secured using an adhesive, then the “low temperature” PVD process is preferably conducted at temperatures below 200° C. and/or below the melting point of the adhesive once cured. In another embodiment, the coating process for the coating 113 may be conducted at a temperature no greater than 150° C. In a further embodiment, the coating process for the coating 113 may be conducted at a temperature no greater than 110° C.

In one embodiment, particularly in the case that the coating 113 is formed of zirconium, the coating process for the coating 113 is conducted for about 5-25 minutes. In another embodiment, the coating process for the coating 113 conducted for 5-20 minutes. In a further embodiment, the coating process for the coating 113 is conducted for 5-10 minutes. This process time ensures a durable coating is applied in a cost-effective manner. Preferably, the coating process of coating 113 is conducted for a shorter time period than the coating process of coating 111, as the coating 113 is generally not subjected to the environment, thus not beholden to same degree of durability as is coating 111.

According to various embodiments, an additional coating or coatings 115 on the club head 100 of another metal, such as a nickel/chrome layer, is applied to the striking face 105. The additional coating or coatings 115 is overlayed by later-applied coatings 111 and 113 to increase the durability and adherence of the coatings 111 and 113. Further, PVD is generally difficult to apply directly to a titanium substrate. Thus, in the case where the striking face insert 107 comprises titanium, the layer 115, particularly when comprising a nickel layer and overlaying chrome (or chromium) layer, may increase the adherence of a later-applied PVD layer, enabling the titanium striking face 105 to be a suitable substrate for a PVD application. The coating 115 may be applied by any of electroplating, sputtering, PVD, or the like.

The coating layer 113, particularly when formed of zirconium, is advantageous at least in that it prevents, or substantially mitigates the onset of, removal of the nickel/chrome layer where location-specific stripping of overlaying layers is necessary in downstream processes.

According to various embodiments, a backing plate or damping member (not shown) may be secured to the golf club head 100, optionally proximate a rear surface of a striking wall of the club head 100. In some embodiments, coatings similar in composition and deposition method to the coatings 111 and/or 113 are provided to overlay the backing plate or damping member 109, or any other component of the golf club head 100.

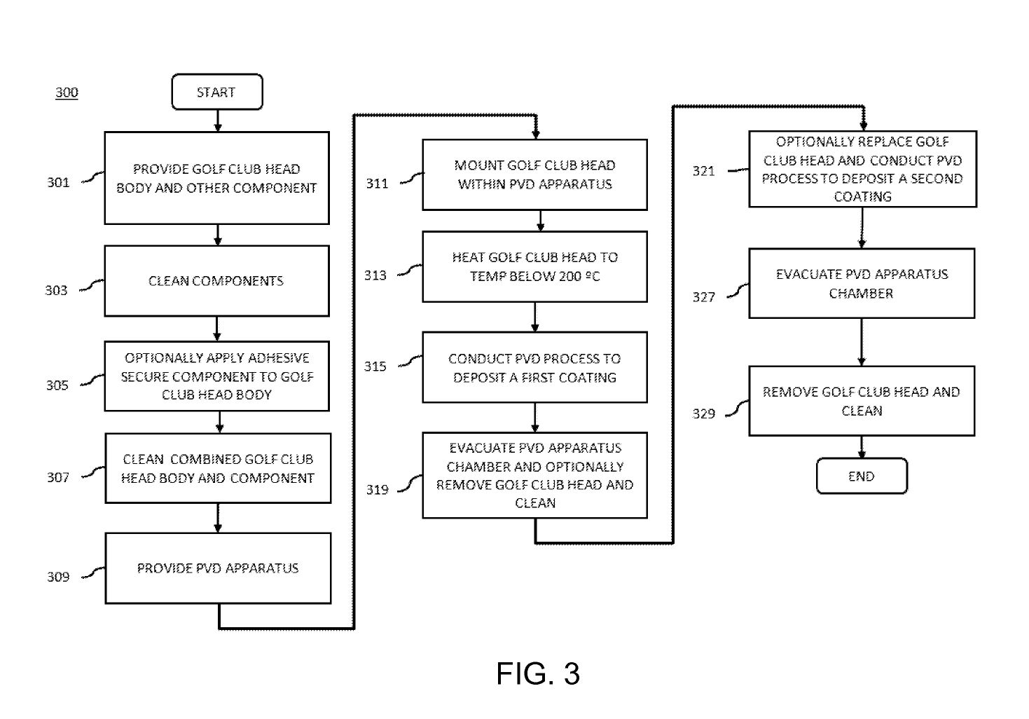

FIG. 3 illustrates a flowchart of a process 300 for providing a coated golf club head 100 by way of a low-temperature PVD process as discussed above. The process begins at step 301 in which the golf club head body 101 comprising a material selected from stainless steel, titanium, aluminum, copper, polymer and a fiber reinforced polymer and a second golf club head component (e.g. striking face insert 107 and/or backing plate or damping member 109) comprising a material selected from stainless steel, titanium, aluminum, copper, polymer and a fiber reinforced polymer, are provided. The golf club head body 101 may have a recess therein for accepting the second golf club head component.

The process continues to step 303 in which the golf club head body 101 and the golf club head component are cleaned. Next, in step 305, an adhesive is optionally applied to at least a portion of one of the golf club head body 101 and the golf club component, and the golf club component is secured to the golf club head body 101, in the recess if one is provided, by any suitable means including mechanical press fitting, interference fitting, welding, pinning or by adhesion. If an adhesive is applied, the adhesive is allowed to cure for from about 20 to about 60 minutes at a temperature ranging from about 120° C. to about 140° C. to form the golf club head 100.

The process continues to step 307 in which the golf club head 100 is thoroughly deburred and cleaned of all contaminants. Preferably, particularly where the portion of the club head to be PVD coated is formed of titanium, the club head is then coated with a nickel-chrome layer, e.g. coating layer 115, to improve adherence of any later-applied PVD coating. A physical vapor deposition apparatus for depositing a metal coating on at least the striking face 105 of the golf club head 100 is provided, in step 309. Then, in step 311, the golf club head 100 is mounted on a substrate support within the PVD apparatus provided. Next, in step 313, the golf club substrate is heated to a temperature that is below 200° C. Additionally, or alternatively, the golf club substrate is heated to a temperature less than the melting point of the adhesive, if previously applied in step 305. In another embodiment, the PVD process may be conducted at a temperature no greater than 150° C. In a further embodiment, the PVD process may be conducted at a temperature no greater than 110° C.

The process continues to step 315 in which a PVD process is conducted, i.e. the PVD apparatus is purged with an inert gas and a predetermined vacuum is established. Coating layer 113 is physical vapor deposited to form a golf club head 100 intermediate. Then, in step 319, the PVD apparatus chamber is evacuated of all material used to form the layer 113, and the golf club head 100 intermediate is optionally removed from the PVD apparatus to remove all excess metal deposited in step 315. In some embodiments, no removal occurs prior to any subsequent PVD coating application, to further improve time efficiency. Preferably, the coating process for the coating 113 is conducted for about 5-25 minutes. In another embodiment, the coating process for the coating 113 conducted for 5-20 minutes. In a further embodiment, the coating process for the coating 113 is conducted for 5-10 minutes.

The process continues to step 321 in which the golf club head 100 intermediate, if removed, is replaced in the PVD apparatus and coating 111 is physical vapor deposited over the layer 113 at a temperature that is below 200° C. Additionally, or alternatively, the golf club substrate is heated to a temperature less than the melting point of the adhesive, if previously applied in step 305. In another embodiment, the PVD process is conducted at a temperature no greater than 150° C. In a further embodiment, the PVD process is conducted at a temperature no greater than 110° C. Preferably, the coating process 321 is conducted for a period of time between about 30 minutes and about 120 minutes, more preferably between about 70 minutes and about 110 minutes, and most preferably about 90 minutes.

Then, in step 327, the PVD apparatus is evacuated. Next, in step 329, the golf club head 100 is removed from the PVD apparatus and cleaned.

While the process discussed above is described with respect to a golf club head 100, the process 300 may be useful in preparing any other article of sporting equipment such as baseball bats, tennis rackets, fishing poles, skis, etc.

Those skilled in the art will appreciate that while the present invention has been described in association with presently preferred aspects thereof, numerous changes, modifications and substitutions of equivalents may be made therein without departing from the spirit and scope of this invention which is intended to be unlimited by the foregoing except as may appear in the following appended claims.

What is claimed is:

1. A method comprising:
securing a first golf club head component to a second golf club head component using an adhesive, resulting in a golf club head main body having an exterior surface; and
physical vapor depositing at least one layer on at least a portion of the exterior surface of the golf club head main body at a temperature less than a melting point of the adhesive.

2. The method of claim 1, wherein the physical vapor deposition of the at least one layer occurs for a predetermined period of time in the range of 5 minutes to 120 minutes.

3. The method of claim 1, wherein the at least one layer includes a first layer comprising a metal chosen from a group consisting of: vanadium, chromium, zirconium, titanium, niobium, molybdenum, hafnium, tantalum, and tungsten, and a nonmetal selected from a group consisting of a nitride, a carbide, and a carbonitride.

4. The method of claim 3, wherein the at least one layer comprises a second layer that is different from the first layer.

5. The method of claim 4, wherein the first layer comprises titanium carbide and the second layer comprises zirconium, the first layer overlaying the second layer.

6. The method of claim 1, wherein at least one of the first golf club head member and the second golf club head member comprises a material selected from the group consisting of:
stainless steel, titanium, aluminum, copper, polymer, and a fiber reinforced polymer.

7. The method of claim 1, wherein:
the first golf club head component comprises a main body portion having a front portion and rear portion, the front portion having a recess therein; and
the second golf club head component comprises a striking face insert configured to be located within the recess of the first golf club head component.

8. The method of claim 1, wherein the physical vapor deposition of one or more of the at least one layer is at a temperature that is no greater than 200° C.

9. The method of claim 8, wherein the physical vapor deposition of one or more of the at least one layer is at a temperature that is no greater than 150° C.

10. The method of claim 9, wherein the physical vapor deposition of one or more of the at least one layer is at a temperature that is no greater than 110° C.

11. The method of claim 4, wherein
the physical deposition of the first layer occurs for a first predetermined period of time; and
the physical deposition of the second layer occurs for a second predetermined period of time different from the first predetermined period of time.

12. The method of claim 1, further comprising:
forming a nickel layer by coating at least a portion of the exterior surface of the golf club head component with nickel; and
forming a chromium layer by coating at least a portion of the exterior surface of the golf club head component with chromium,
wherein the at least one layer overlays each of the nickel layer and the chromium layer.

13. A golf club head comprising:
a first club head component;
a second club head component secured to the first club head component;
an adhesive material interposed between the first club head component and the second club head component, the adhesive material having a melting point;
an exterior surface; and
at least one layer that is physical vapor deposited on at least a portion of the exterior surface of the golf club head at a temperature less than the melting point of the adhesive.

14. The golf club head of claim 13, wherein the at least one layer includes a first layer comprising a metal chosen from a group consisting of: vanadium, chromium, zirconium, titanium, niobium, molybdenum, hafnium, tantalum, and tungsten, and a nonmetal selected from a group consisting of a nitride, a carbide, and a carbonitride.

15. The golf club head of claim 14, wherein the at least one layer comprises a second layer that is different from the first layer.

16. The golf club head of claim 15, wherein the first layer comprises titanium carbide and the second layer comprises zirconium, the first layer overlaying the second layer.

17. The golf club head of claim 13, wherein the golf club head comprises a material selected from the group consisting of: stainless steel, titanium, aluminum, copper, polymer, and a fiber reinforced polymer.

18. The golf club head of claim 13, wherein:
the first club head component comprises a return portion having a front portion and rear portion, the front portion having a recess therein; and
the second club head component comprises a striking face insert configured to be located within the recess of the first club head component.

19. The golf club head of claim 13, further comprising:
a nickel coating layer; and
a chromium coating layer,
wherein the at least one layer overlays each of the nickel coating layer and the chromium coating layer.

20. A method for preparing a golf club component comprising:
providing a golf club component of a first material, the golf club component having an exterior surface;
physical vapor depositing at least one layer on at least a portion of the exterior surface of the club head component at a temperature no greater than 200° C.

21. The method of claim 20, wherein the at least one layer includes a first layer comprising a metal chosen from a group consisting of: vanadium, chromium, zirconium, titanium, niobium, molybdenum, hafnium, tantalum, and tungsten, and a nonmetal selected from a group consisting of a nitride, a carbide, and a carbonitride.

22. The method of claim 21, wherein the at least one layer comprises a second layer that is different from the first layer.

23. The method of claim 22, wherein the first layer comprises titanium carbide and the second layer comprises zirconium, the first layer overlaying the second layer.

24. The method of claim 20, wherein the golf club component comprises a material selected from the group consisting of: stainless steel, titanium, aluminum, copper, polymer, and a fiber reinforced polymer.

25. The method of claim 20, wherein the golf club component comprises a first sub-component and a second sub-component secured to the first sub-component using an adhesive.

26. The method of claim 20, wherein the physical vapor deposition of one or more of the at least one layer is at a temperature that is no greater than 150° C.

27. The method of claim 20, further comprising the steps of:
forming a nickel layer by coating at least a portion of the exterior surface of the golf club component with nickel; and
forming a chromium layer by coating at least a portion of the exterior surface of the golf club component with chromium,
wherein the at least one layer overlays each of the nickel layer and the chromium layer.
